(19) United States
(12) Patent Application Publication
(10) Pub. No.: US 2017/0244064 A1
(43) Pub. Date: Aug. 24, 2017

(54) DISPLAY DEVICE AND METHOD FOR MANUFACTURING DISPLAY DEVICE

(71) Applicant: Japan Display Inc., Minato-ku (JP)

(72) Inventors: Akinori KAMIYA, Minato-ku (JP); Hiroki OHARA, Minato-ku (JP)

(73) Assignee: Japan Display Inc., Minato-ku (JP)

(21) Appl. No.: 15/360,185

(22) Filed: Nov. 23, 2016

(30) Foreign Application Priority Data
Feb. 19, 2016 (JP) 2016-030161

(51) Int. Cl. H01L 51/52

(52) U.S. Cl. CPC H01L 51/5253; H01L 51/5284; H01L 51/5237; H01L 2251/303

(57) ABSTRACT

A display device includes a light-emitting element layer that emits light in a way that unit pixels each forming a pixel are respectively controlled in brightness, a sealing layer provided on the light-emitting element layer, an ultraviolet absorbing layer provided on the sealing layer, and a flattening layer provided on the ultraviolet absorbing layer and made of organic resin having ultraviolet curability.

### CROSS-REFERENCE TO RELATED APPLICATION

The present application claims priority from Japanese application JP2016-030161 filed on Feb. 19, 2016 the content of which is hereby incorporated by reference into this application.

### BACKGROUND OF THE INVENTION

1. Field of the Invention

The present invention relates to a display device and a method for manufacturing the display device.

2. Description of the Related Art

There have been known display devices including a light-emitting element layer that emits light by controlling brightness in each unit pixel forming an image and a sealing layer that covers the light-emitting element layer. The sealing layer is provided so as to prevent moisture from outside penetrating into the inside of the device. As disclosed in JP2013-105947A, for example, a display device including a sealing layer formed of an inorganic material, a flattening layer formed of organic resin and stacked on the sealing layer, and a sealing layer formed of an inorganic material and stacked on the flattening layer has been known as a display device including a sealing layer. The flattening layer is formed of acrylic resin having ultraviolet curability, for example, hardened by being irradiated with ultraviolet rays, and formed on the light-emitting element layer.

When the flattening layer is irradiated with ultraviolet rays, the light-emitting element layer below the flattening layer may be affected by the ultraviolet rays, thereby degrading light emitting characteristics.

### SUMMARY OF THE INVENTION

It is an object of the invention to provide a display device that prevents a light emitting characteristics from being degraded, and a method for manufacturing the display device.

A display device according to one aspect of the present Invention includes a substrate, a light-emitting element layer that is provided on the substrate and emits light by controlling brightness in each unit pixel forming an image, a sealing structure provided on the light-emitting element layer, and an ultraviolet absorbing layer provided on the light-emitting element layer, wherein the sealing structure includes a first flattening layer that is provided on the ultraviolet absorbing layer and made of organic resin having ultraviolet curability.

A method for manufacturing a display device according to another aspect of the present invention includes the steps of preparing a substrate, providing a light-emitting element layer on the substrate, providing a sealing layer made of an inorganic material on the light-emitting element layer, providing an ultraviolet absorbing layer on the sealing layer, providing an organic resin having ultraviolet curability on the ultraviolet absorbing layer, and irradiating the organic resin with a ultraviolet ray so as to cure the organic resin.

### BRIEF DESCRIPTION OF THE DRAWINGS

In the accompanying drawings:

FIG. 1 is an external perspective view of a display device according to first to third embodiments;

FIG. 2 is a schematic sectional view illustrating a cross section of the display device according to the first embodiment;

FIG. 3 is a circuit diagram illustrating a circuit formed on each pixel;

FIG. 4 is a flow chart of a method for manufacturing the display device according to the first embodiment;

FIG. 5 is a schematic sectional view illustrating a cross section of the display device according to the second embodiment; and

FIG. 6 is a schematic sectional view illustrating a cross section of the display device according to the third embodiment.

### DETAILED DESCRIPTION OF THE INVENTION

The embodiments of the present invention will be described below with reference to the accompanying drawings.

In the embodiments of the present invention, when a manner in which a structure is disposed “on” another structure is described, it is understood, if not otherwise stated, that simply describing “on” includes both a case in which the structure is disposed directly on the another structure in contact with each other and a case in which the structure is disposed above or over the another structure with a third structure interposed therebetween.

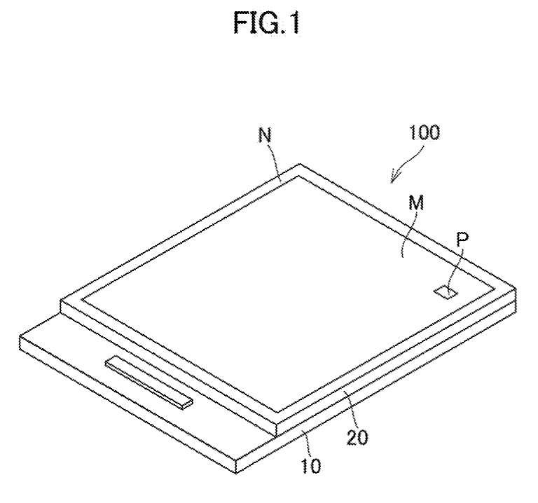

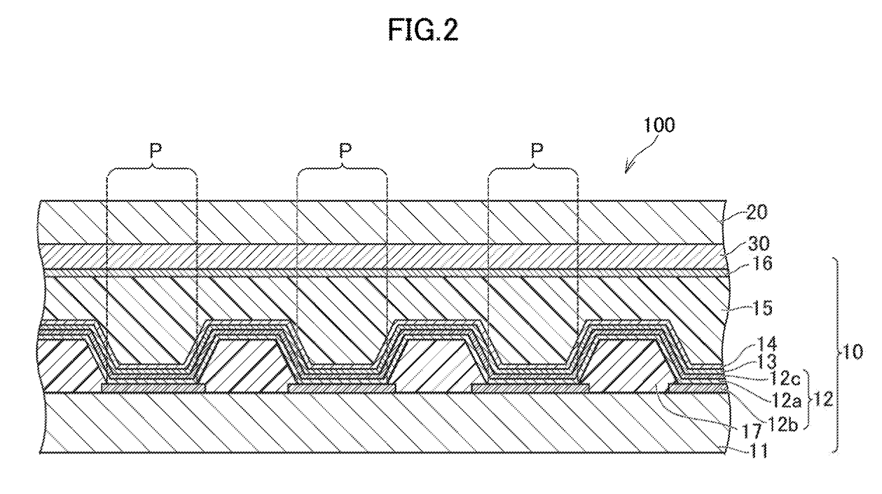

Referring to FIGS. 1 and 2, the overall general configuration of the display device according to the first embodiment will be discussed. FIG. 1 is an external perspective view of a display device according to the first embodiment. FIG. 2 is a schematic sectional view illustrating a cross section of the display device according to the first embodiment. In the first embodiment, a so-called organic electro luminescence (EL) display device using an organic EL element will be discussed as the display device, although the display device is not limited to this but may be a display device including a layer that emits light in a way that unit pixels P each forming a pixel are respectively controlled in brightness.

As shown in FIG. 1, a display device 100 includes a TFT (Thin Film Transistor) substrate 10 having a thin film transistor, for example, and a counter substrate 20. As shown in FIG. 2, the counter substrate 20 is provided to oppose the TFT substrate 10 via a filler 30. The display device 100 includes a display area M for image display and a frame area N around the display area M. A plurality of unit pixels P are provided in the display area M. In FIG. 1, only one unit pixel P is shown, although in reality a plurality of unit pixels P are arranged on the display area M in a matrix.

As shown in FIG. 2, the TFT substrate 10 includes a substrate 11, a light-emitting element layer 12 provided on the substrate 11, a sealing layer 13 provided on the light-emitting element layer 12 and formed of an inorganic material, a ultraviolet absorbing layer 14 provided on the sealing layer 13, a flattening layer 15 provided on the ultraviolet absorbing layer 14 and formed of organic resin, and a sealing layer 16 provided on the sealing layer 15 and formed of an inorganic material. In the following, details of each layer and substrate included in the TFT substrate 10 will be discussed.

The substrate 11 has at least a circuit layer including a wiring. The details of the wiring of the circuit layer will be discussed later. The substrate 11 may be a resin substrate made of flexible polyimide, for example, or a glass substrate.

The light-emitting element layer 12 is a layer that emits light in a way that the unit pixels P each forming a pixel are respectively controlled in brightness. The light-emitting element layer 12 is a layer that is at least provided on the display area M, and includes an organic EL layer 12a, a lower electrode 12b provided in the lower part of the organic EL layer 12a, and an upper electrode 12c provided in the upper part of the organic EL layer 12a. Although not shown here in detail, the organic EL layer 12a includes a charge transport layer, a charge injection layer, and a light-emitting layer, for example.

In the organic EL layer 12a, an area in contact with the lower electrode 12b corresponds to respective unit pixels P, and light is emitted in this area. The unit pixels P are divided by a bank layer 14, and an area where the organic EL layer 12a and the lower electrode 12b are separated by the bank layer 14 does not emit light. The upper electrode 12c is disposed on the organic EL layer 12a across the unit pixels P. In the first embodiment, the lower electrode 12b and the upper electrode 12c are an anode and a cathode, respectively, but are not limited to these, and the polarity may be reversed. The upper electrode 12c, through which light from the organic EL layer 12a passes, may be formed as a transmission electrode using transparent conductive material, for example. Materials such as indium tin oxide (ITO) or indium zinc oxide (IZO) may be used as the transparent conductive material. Alternatively, the upper electrode 12c may be formed in a thin film using aluminum (Al), silver (Ag), or alloy of Ag and magnesium (Mg) in a thickness that allows light to pass therethrough, or formed in a laminated film of these metal thin films and the transparent conductive material.

The first embodiment may employ a color-separation method for splitting the organic EL layer 12a to emit light of colors according to colors of pixels, or a color filter method in which all pixels emit light of the same color (e.g., white) and only light in a predetermined wavelength in each pixel transmits a color filter provided on the counter substrate 20.

The sealing layers 13 and 16 are provided so as to prevent moisture ingress from outside penetrating into the display device 100. The sealing layers 13 and 16 are made of silicon nitride (SiN), but not limited to this, and may be made of any inorganic material excellent in moisture resistance, such as silicon oxide. The flattening layer 15 is made of acrylic resin, but not limited to this, and may be made of any organic resin having ultraviolet curability, such as epoxy resin.

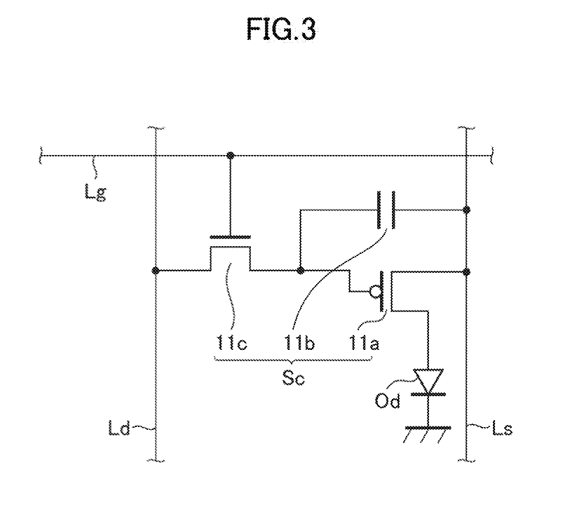

Referring to FIGS. 2 and 3, the principle of light emission of the light-emitting element layer will be discussed. FIG. 3 is a circuit diagram illustrating a circuit formed on each unit pixel P. As shown in FIG. 3, a wiring of the circuit layer included in the substrate 11 has a scanning line Lg, a video signal line Ld orthogonal to the scanning line Lg, and a power source line Ls orthogonal to the scanning line Lg. A pixel control circuit Sc is provided on each unit pixel P of the circuit layer, and the pixel control circuit Sc is connected to the lower electrode 12b through a contact hole (not shown). The pixel control circuit Sc includes a thin film transistor and a capacitor, and controls power supply to an organic light-emitting diode Od provided to each unit pixel P. The organic light-emitting diode Od is composed of the organic EL layer 12a, the lower electrode 12b, and the upper electrode 12c, each described above referring to FIG. 2.

As shown in FIG. 3, the pixel control circuit Sc includes a drive TFT 11a, a storage capacitor 11b, and a switching TFT 11c. The gate of the switching TFT 11c is connected to the scanning line Lg, and the drain of the switching TFT 11c is connected to the video signal line Ld. The source of the switching TFT 11c is connected to the storage capacitor 11b and the gate of the drive TFT 11a. The drain of the drive TFT 11a is connected to the power source line Ls, and the source of the drive TFT 11a is connected to the organic light-emitting diode Od. When a gate voltage is applied to the scanning line Lg, the switching TFT 11c is ON state. At this time, when a video signal is supplied from the video signal line Ld, charges are stored in the storage capacitor 11b. By the charges stored in the storage capacitor 11b, the drive TFT 11a is caused to be ON state. A current then flows from the power source line Ls to the organic light-emitting diode Od, and the organic light-emitting diode Od emits light.

The pixel control circuit Sc may be any circuit for controlling current supply to the organic light-emitting diode Od, and not to be limited to the one shown in FIG. 3. For example, the pixel control circuit Sc may further include an auxiliary capacitor other than the storage capacitor 11b in order to increase the capacity. The polarity of the transistors constituting the circuit is also not limited to an example shown in FIG. 3.

In the first embodiment, the ultraviolet absorbing layer 14 is made Of titanium oxide (TiOₓ, x principally is 2) having transparency. The titanium oxide absorbs an ultraviolet ray at a wavelength of 365 nm, and has property of transmitting visible light. The ultraviolet absorbing layer 14 is provided to protect the light-emitting element layer 12 from an ultraviolet ray. The ultraviolet absorbing layer 14 is not limited to be made of titanium oxide, but may be a layer made of any material that absorbs an ultraviolet ray and transmits light from the light-emitting element layer 12.

In the display device 100 according to the first embodiment, the ultraviolet absorbing layer 14 is disposed between the light-emitting element layer 12 and the flattening layer 15, which is provided on the light-emitting element layer 12 and made of organic resin having ultraviolet curability, and thus the light-emitting element layer 12 is less likely to be affected by a ultraviolet ray even if the ultraviolet ray is irradiated to cure the flattening layer 15. As such, it is possible to prevent deterioration of the light-emitting element layer 12 due to irradiation of ultraviolet rays, to thereby prevent shortening of the life of the device.

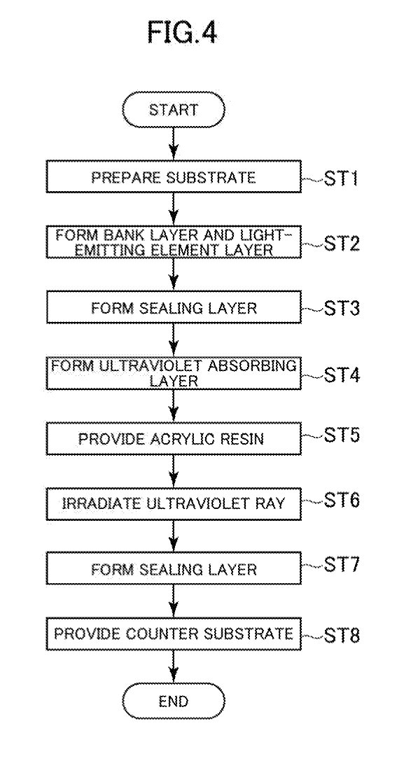

Next, referring to FIG. 4, a method for manufacturing the display device according to the first embodiment will be discussed. FIG. 4 is a flow chart of the method for manufacturing the display device according to the first embodiment.

First, a substrate 11 including a circuit layer is prepared (Step ST1). Subsequently, a bank layer 14 and a light-emitting element layer 12 are formed on the substrate 11 (Step ST2). Further, a sealing layer 13 composed of silicon nitride is formed on the light-emitting element layer 12, using materials that includes silicon, ammonia gas, and nitrogen gas, by a chemical vapor deposition (CVD) method (Step ST3) . A plasma CVD method may be employed as the CVD method to turn source gas into plasma and initiate a chemical reaction. In this step, a reaction between silicon and ammonia gas generates silicon nitride, and nitrogen gas is used for adjusting pressure. The sealing layer 13 is formed along with a shape of the light-emitting element layer 12.

Further, an ultraviolet absorbing layer 14 composed of titanium oxide having ultraviolet ray absorbency is formed on the sealing layer 13 (Step ST4). Subsequently, acrylic resin is provided on the ultraviolet absorbing layer 14 (Step ST5). Thereafter, the fluid acrylic resin is irradiated with ultraviolet rays so as to be cured (Step ST6). The acrylic resin irradiated with ultraviolet rays is cured, and with this, a flattening layer 15 is formed as a resin layer. Upon receiving ultraviolet rays, the ultraviolet absorbing layer 14 composed of titanium oxide exhibits a hydrophilic property. As such, wettability of the acrylic resin provided on the ultraviolet absorbing layer 14 is enhanced. For this reason, compared to a case where the flattening layer 15 is directly formed on the sealing layer 13, the flattening layer 15 is evenly and uniformly formed on the ultraviolet absorbing layer 14.

A sealing layer 16 composed of silicon nitride is then formed on the flattening layer 15 (Step ST7). The sealing layer 16 may be formed by the same method as the sealing layer 13. The method for forming the sealing layers 13 and 16 each composed of an inorganic material is not limited to the CVD method, but other methods such as a sputtering method or an atomic layer deposition (ALD) method may also be used. The ultraviolet absorbing layer 14 may also be formed by the CVD method similarly to the sealing layers 13 and 16, or by other methods such as a sputtering method or an ALD method. With the steps above, manufacturing of the TFT substrate 10 is completed.

After Step ST7 is completed, a counter substrate 20 is provided to oppose to the TFT substrate 10 through a filler layer 30 (Step ST8). The display device 100 according to the first embodiment is manufactured through the steps described above.

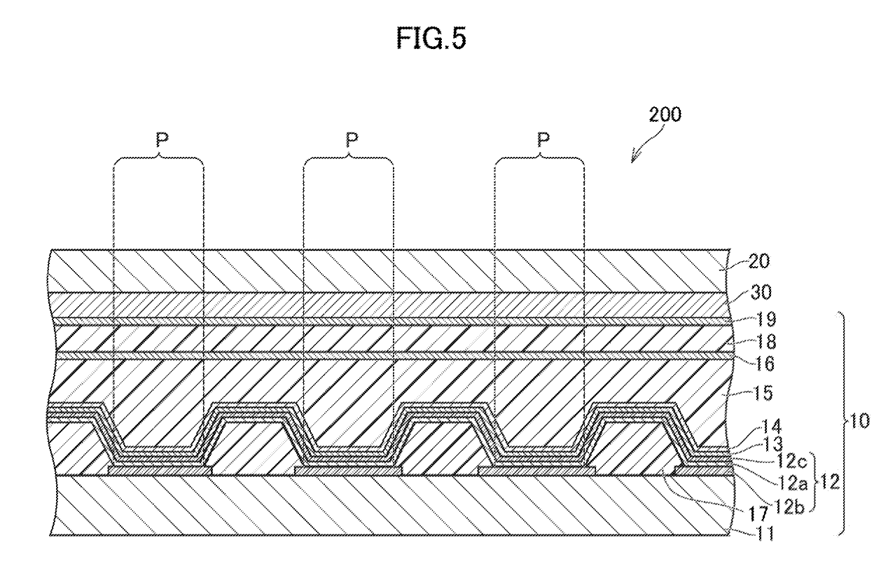

Referring to FIG. 5, a display device 200 according to the second embodiment will be discussed. FIG. 5 is a schematic sectional view illustrating a cross section of the display device according to the second embodiment. The display device 200 has the same structure as the display device 100 except having a flattening layer 18 and a sealing layer 19. Specifically, the display device 200 includes a sealing layer 13 provided on a light-emitting element layer 12, an ultraviolet absorbing layer 14 provided on the sealing layer 13, a flattening layer 15 provided on the ultraviolet absorbing layer 14, a sealing layer 16 provided on the flattening layer 15, a flattening layer 18 provided on the sealing layer 16, and a sealing layer 19 provided on the flattening layer 18.

The flattening layer 18 may be formed using the same material and the same method as the flattening layer 15. Further, the sealing layer 19 may be formed using the same material and the same method as the sealing layer 16. In this way, the flattening layers composed of organic resin are provided doubly in the display device 200, and thus it is possible to form a more flat and smooth layer than that of the display device 100. Further, the triple sealing layers composed of an inorganic material are provided, and thus, compared to the display device 100, it is possible to more readily prevent moisture ingress into the inside of the device. At the time the flattening layer 15 and the flattening layer 18 are formed, the layers respectively need to be irradiated with ultraviolet rays so that the organic resin is cured. In either case of ultraviolet-ray irradiation, the ultraviolet absorbing layer 14 absorbs ultraviolet rays, and serves to reduce an influence of the ultraviolet rays on the light-emitting element layer 12.

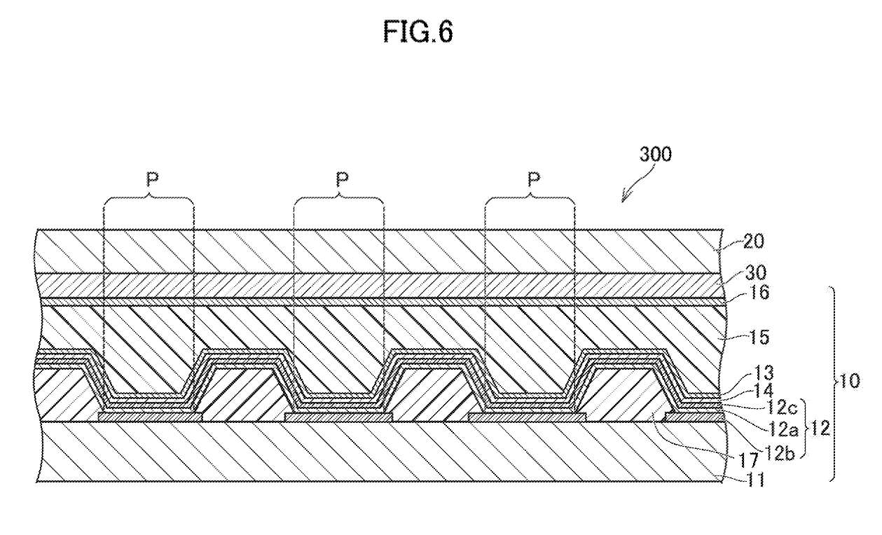

Referring to FIG. 6, a display device 300 according to the third embodiment will be discussed. FIG. 6 is a schematic sectional view illustrating a cross section of the display device according to the third embodiment. The display device 300 has the same structure as the display device 100 except that the sealing layer 13 and the ultraviolet absorbing layer 14 are laminated in a different order. Specifically, the display device 300 includes an ultraviolet absorbing layer 14 provided on a light-emitting element layer 12, a sealing layer 13 provided on the ultraviolet absorbing layer 14, a flattening layer 15 provided on the sealing layer 13, and a sealing layer 16 provided on the flattening layer 15. In this structure as well, similarly to the first embodiment, when the flattening layer 15 composed of organic resin having ultraviolet curability is irradiated with ultraviolet rays so as to be cured, the ultraviolet absorbing layer 14 absorbs the ultraviolet rays, and thus the light-emitting element layer 12 is less influenced by the ultraviolet rays.

The laminated structure of the sealing layers 13 and 16 and the flattening layer 15 as described in the first embodiment corresponds to the sealing structure of the present invention. Further, the laminated structure of the sealing layers 13, 16, and 19, and the flattening layers 15 and 18 as described in the first to the third embodiments corresponds to the sealing structure of the present invention, the sealing layer 13 corresponds to the first sealing layer of the present invention, the sealing layer 16 corresponds to the second sealing layer of the present invention, the flattening layer 15 corresponds to the first flattening layer, and the flattening layer 18 corresponds to the second flattening layer. While there have been described what are at present considered to be certain embodiments of the invention, it will be understood that various modifications may be made thereto, and it is intended that the appended claims cover all such modifications as fall within the true spirit and scope of the invention.

What is claimed is:

1. A display device comprising:
a substrate;
a light-emitting element layer provided on the substrate; and
a sealing structure and an ultraviolet absorbing layer, each provided on the light-emitting element layer, wherein
the sealing structure includes a first flattening layer made of organic resin having ultraviolet curability, and
the first flattening layer is provided on the ultraviolet absorbing layer.

2. The display device according to claim 1, wherein
the sealing structure includes a first sealing layer made of an inorganic material between the light-emitting element layer and the ultraviolet absorbing layer.

3. The display device according to claim 1, wherein
the sealing structure includes a first sealing layer made of an inorganic material between the ultraviolet absorbing layer and the first flattening layer.

4. The display device according to claim 1, wherein
the ultraviolet absorbing layer is made of titanium oxide.

5. The display device according to claim 1, wherein
the sealing structure is provided on the first flattening layer and includes a second sealing layer made of an inorganic material and a second flattening layer provided on the second sealing layer and made of organic resin.

6. A display device comprising:
a substrate;
a light-emitting element layer provided on the substrate; and
a sealing structure and a titanium oxide layer, each provided on the light-emitting element layer, wherein
the sealing structure includes a first flattening layer made of organic resin, and
the first flattening layer is provided on the titanium oxide layer.

7. The display device according to claim 6, wherein
the sealing structure includes a first sealing layer made of an inorganic material between the light-emitting element layer and the titanium oxide layer.

8. The display device according to claim 6, wherein
the sealing structure includes a first sealing layer made of an inorganic material between the titanium oxide layer and the first flattening layer.

9. The display device according to claim 6, wherein
the sealing structure includes a second sealing layer provided on the first flattening layer and made of an inorganic material, and a second flattening layer provided on the second sealing layer and made of organic resin.

10. A method for manufacturing a display device, comprising the steps of:
preparing a substrate;
providing a light-emitting element layer on the substrate;
providing a sealing layer made of an inorganic material on the light-emitting element layer;
providing an ultraviolet absorbing layer on the sealing layer;
providing organic resin having ultraviolet curability on the ultraviolet absorbing layer; and
irradiating the organic resin with a ultraviolet ray so as to cure the organic resin.

11. The method for manufacturing a display device according to claim 10, further comprising the step of providing a second sealing layer made of an inorganic material on the organic resin.
